(19) United States
(12) Patent Application Publication
(10) Pub. No.: US 2022/0357387 A1
(43) Pub. Date: Nov. 10, 2022

(54) MONITORING THE STATE OF OVERVOLTAGE PROTECTION COMPONENTS

(71) Applicant: LEONI KABEL GMBH, Roth (DE)

(72) Inventors: REIKO SAENGER, Lauscha (DE); HAKAN SAYINC, Berlin (DE); PETER RIEDEL, Jena (DE); OLIVER SCHADOW, Stahnsdorf (DE)

(21) Appl. No.: 17/617,030

(22) PCT Filed: May 18, 2020
(86) PCT No.: PCT/EP2020/063773

§ 371 Date: Dec. 7, 2021

(30) Foreign Application Priority Data
Jun. 14, 2019 (DE) 10 2019 116 233.5

(51) Int. Cl. G01R 31/12; G01D 5/353; H02H 7/16

(52) U.S. Cl. CPC G01R 31/1236; G01D 5/35316; H02H 7/16

(57) ABSTRACT

The invention relates to a system and a method for monitoring the state of at least one over voltage protection component. The system has a transmission unit and a connection assembly coupled to the transmission unit. The system additionally has at least one measuring assembly coupled to the connection assembly. The at least one measuring assembly is designed to be arranged in at least one over voltage protection component. The system additionally has an analysis unit coupled to the at least one measuring assembly.

The present invention relates generally to monitoring the state of over voltage protection components. Specifically, the present invention relates to a system and a method for monitoring the state of at least one over voltage protection component.

Over voltages can result in damage to electrical and electronic components. For example, over voltages can be caused by direct or nearby lightning strikes, by an electromagnetic pulse, by electrostatic discharges or by switching processes in the power supply system and in devices and can accordingly in some cases have considerable instantaneous powers.

In order to protect against such over voltages, various devices, components or structural elements are nowadays used, according to the intended purpose. There come into consideration as over voltage arresters e.g. spark gaps, gas-filled over voltage arresters (also referred to as gas arresters), varistors or suppressor diodes. With suppressor diodes, in particular the signal inputs of electrical devices at low voltages are secured. Varistors protect the mains voltage input of devices or areas of the power supply system that are at risk (e.g. lightning protection for buildings, inputs and outputs of large transformers and traction substations). Gas arresters are used to protect signal lines and in some cases also mains lines when very high discharge energies are expected.

Over voltage arresters and over voltage protection components and also high-voltage protection components in general are in some cases exposed to high loads because of their function, namely protection against in some cases very high voltages. The high loads can result in damage to or even the failure of over voltage protection components.

In order to eliminate this problem, corresponding over voltage protection systems are often over dimensioned in order to ensure a desired fail-safety. The over dimensioning results in inefficient dimensioning of such systems and installations. More efficient dimensioning of over voltage protection systems is desirable. However, more efficient dimensioning requires over voltage protection components of an over voltage protection system to be monitored in an ideally targeted, accurate and/or prompt manner.

There is therefore a need for targeted, accurate and/or prompt monitoring of over voltage protection components.

According to a first aspect of the invention, a system for monitoring the state of at least one over voltage protection component is provided. The system has a transmission unit and a connection assembly coupled with the transmission unit. The system further has at least one measuring assembly coupled with the connection assembly. The at least one measuring assembly is able to be arranged in or on at least one over voltage protection component. In other words, the at least one measuring assembly is configured to be arranged in or on at least one over voltage protection component. In other words, the at least one measuring assembly is configured for arrangement in or on at least one over voltage protection component. The system further has an evaluation unit coupled with the at least one measuring assembly. The transmission unit is configured to transmit a signal. The transmission unit and the connection assembly are coupled such that the signal is able to be coupled into the connection assembly. The connection assembly is configured and arranged so as to guide the coupled-in signal in the direction of the at least one measuring assembly. The connection assembly and the at least one measuring assembly are coupled with one another such that the signal is able to be coupled into the at least one measuring assembly. The at least one measuring assembly is configured to reflect the signal, in dependence on a state of the at least one over voltage protection component, such that information about the state of the at least one over voltage protection component is able to be derived from the reflected signal by the evaluation unit.

With the system, a state of the at least one over voltage protection component can be monitored in a targeted and/or accurate and/or prompt manner. It can be concluded from the state of the at least one over voltage protection component whether the at least one over voltage protection component is functioning normally/abnormally. For example, an abnormal state can indicate a problem in and/or damage to the at least one over voltage protection component. Although reference is made herein in each case to only one signal, multiple signals can be used in a corresponding manner. The transmission unit is accordingly configured to transmit multiple signals.

The signal can be an optical signal. The optical signal can be an analog optical signal. The optical transmission unit can be configured to transmit an optical signal, for example an analog optical signal. In this case, the transmission unit can be referred to as an optical transmission unit. The measuring assembly can be configured to reflect an optical signal, for example an analog optical signal. In this case, the measuring assembly can be referred to as an analog optical measuring assembly.

The signal can be a digitally modulated signal. The digitally modulated signal can be a discrete-valued and continuous-time signal. The digital transmission unit can be configured to transmit a digitally modulated signal. In this case, the transmission unit can be referred to as a digital transmission unit. The digitally modulated signal can, for example, be converted into an optical signal after it has been transmitted by the transmission unit. In this case, the signal can be referred to, for example, as a digital optical signal. For example, the digitally modulated signal can be converted into an optical signal after it has been transmitted but before it is coupled into the connection assembly. The measuring assembly can be configured to reflect a digitally modulated signal or a digital optical signal. In this case, the measuring assembly can be referred to as a digital optical measuring assembly.

The at least one over voltage protection component can be in the form of at least one over voltage arrester or can be part of an over voltage arrester. The evaluation unit can have the transmission unit or, conversely, the transmission unit can have the evaluation unit. The transmission unit and the evaluation unit can be arranged together in a common unit (transmission/evaluation unit). Alternatively, the transmission unit and the evaluation unit can be arranged separately from one another in different entities.

The at least one measuring assembly can have a fiber and a measuring component connected to the fiber. The fiber of the at least one measuring assembly is configured and arranged so as to guide the signal in the direction of the measuring component of the at least one measuring assembly. The fiber can be in the form of an optical fiber. The optical fiber can regarded as at least partially optically conductive. In the case of the use of an optical signal, e.g. an analog optical signal or a digital optical signal, the optical fiber can guide the optical signal.

The measuring component can be in the form of an optically acting/optical measuring component. The measuring component can have a fiber Bragg grating or can be in the form of a fiber Bragg grating. Additionally or alternatively, the measuring component can have one or more crystals or can be in the form of one or more crystals. Additionally or alternatively, the measuring component can have one or more fluorescent dyes or can be in the form of one or more fluorescent dyes.

According to one exemplary embodiment, the connection assembly has an underground cable coupled with the evaluation unit. According to the exemplary embodiment, the connection assembly has an isolator coupled with the underground cable and with the at least one measuring assembly. The isolator can have optically isolating properties at least in part. In other words, the isolator can have, at least in part or in some portions, a material in which an optical signal cannot propagate. Additionally or alternatively, the isolator can have electrically isolating properties at least in part. In other words, the isolator can have, at least in part or in some portions, a material in which an electric current cannot flow. The transmission unit is configured to transmit a signal. The underground cable is coupled with the transmission unit such that the signal transmitted by the transmission unit is able to be coupled into the underground cable. The underground cable is configured and arranged so as to guide the coupled-in signal through the underground cable in the direction of the isolator. The isolator has at least one conductor, e.g. at least one optical conductor, for example at least one optical waveguide, and is coupled with the underground cable such that the signal guided through the underground cable in the direction of the isolator is able to be coupled into the at least one conductor, e.g. the at least one optical conductor, for example the at least one optical waveguide, of the isolator. The at least one conductor, e.g. the at least one optical conductor, for example the at least one optical waveguide, of the isolator is configured and arranged so as to guide the optical signal coupled into the at least one conductor, e.g. the at least one optical conductor, for example the at least one optical waveguide, through the at least one conductor, e.g. the at least one optical conductor, for example the at least one optical waveguide, in the direction of the at least one measuring assembly. The at least one measuring assembly and the isolator are coupled with one another, for example releasably, such that the signal guided through the at least one conductor, e.g. the at least one optical conductor, for example the at least one optical waveguide, of the isolator in the direction of the at least one measuring assembly is able to be coupled into the measuring assembly. For example, the at least one measuring assembly and the isolator can be coupled with one another, for example releasably, such that the signal guided through the at least one conductor, e.g. the at least one optical conductor, for example the at least one optical waveguide, of the isolator in the direction of the at least one measuring assembly is able to be coupled into the at least one fiber of the at least one measuring assembly.

The connections or couplings mentioned herein can have one or more plug connections or one or more splice connections or can be in the form of one or more plug connections or in the form of one or more splice connections.

The state of the over voltage protection component can exhibit a temperature, a tensile stress, a compressive stress and/or a degree of moisture of the over voltage protection component or can be a temperature, a tensile stress, a compressive stress and/or a degree of moisture of the over voltage protection component.

With the system, the state, for example a temperature, a tensile stress, a compressive stress and/or a degree of moisture, of at least one over voltage protection component can be monitored accurately. Tensile stress and/or compressive stress of the at least one over voltage protection component can thereby be understood as being a tensile stress and/or compressive stress acting on the at least one over voltage protection component. It can be concluded from the temperature, the tensile stress, the compressive stress and/or the degree of moisture of the at least one over voltage protection component whether the at least one over voltage protection component is functioning normally/abnormally. For example, too high a temperature of the at least one over voltage protection component can indicate a problem in the at least one over voltage protection component or degradation of the at least one over voltage protection component. In the case of degradation, fault currents increasingly flow, which, owing to the resistance of the over voltage protection component, are converted into heat, which leads to an increase in temperature.

The system can have a connecting device. The connecting device is configured to couple or connect the isolator, for example releasably, to the at least one measuring assembly and/or to the at least one over voltage protection component.

By means of the connecting device, the isolator can be coupled or connected, for example releasably, to the at least one measuring assembly and/or to the at least one over voltage protection component. Moreover, via the connection/coupling of the isolator to the at least one measuring assembly and/or to the at least one over voltage protection component by means of the connecting device, the signal can be guided from the isolator to the at least one measuring assembly and/or from the isolator to the at least one over voltage protection component, or vice vera. The connecting device is in particular designed to be suitable for outdoors. For example, the connecting device can be designed for all conceivable climatic conditions outdoors. In addition, the connecting device can have a high-voltage strength that is suitable or sufficient for the particular application.

The connecting device can be in the form of a plug connection/plug connector or can have a plug connection/plug connector. The connecting device can have a connecting component and a plug connected to the connecting component. The connecting component can have at least one fiber, e.g. an optical fiber. The fiber of the connecting component is able to be connected or is connected to the isolator such that the signal, for example optical signal, guided through the at least one conductor, e.g. the at least one optical conductor, for example the at least one optical waveguide, of the isolator is able to be coupled into the at least one fiber, e.g. optical fiber, of the connecting component. The plug is configured to establish a releasable coupling or connection between the connecting component and the at least one measuring assembly and/or the at least one over voltage protection component.

The connecting component is designed in particular to be suitable for outdoors. For example, the connecting component can be designed for all conceivable climatic conditions outdoors. In addition, the connecting component can have a high-voltage strength that is suitable or sufficient for the particular application. The plug can be designed to be suitable for outdoors. The plug can be water-tight, for example. Additionally or alternatively, the plug can have a metallic material or be formed of a metallic material. The releasable connection between the connecting component and the at least one measuring assembly and/or the at least one over voltage protection component via the plug permits a comparatively simple and low-risk installation.

The system can have a coupling device which can be mounted on the at least one measuring assembly and/or on the at least one over voltage protection component. The coupling device can be releasably connectable to the plug. The coupling device can be configured to seal the transition region between the plug and the at least one measuring assembly and/or the at least one over voltage protection component. As a result, function-impairing moisture cannot penetrate the at least one measuring assembly and/or the at least one over voltage protection component. The signal is, however, able to pass through the transition region between the plug and the at least one measuring assembly and/or the at least one over voltage protection component.

The fiber of the at least one optical measuring assembly can be couplable with the plug such that the signal is able to be coupled via the plug into the fiber, e.g. the optical fiber. For example, the fiber of the at least one measuring assembly can be configured and arranged such that it runs from the plug or from the coupling device to the measuring component of the at least one measuring assembly.

The fiber can, for example, be embedded with the measuring component in a placeholder of the or in the over voltage protection component. Specific details thereof will be described hereinbelow.

The system can further have the at least one over voltage protection component. In other words, the at least one over voltage protection component can be part of the system.

The at least one over voltage protection component can, for example, have at least one varistor or can be in the form of at least one varistor. Varistors are voltage-dependent resistors. They change their resistance value in dependence on the applied voltage. They are therefore also called voltage-dependent resistors (VDR). The resistance value of a varistor falls as the voltage increases. When the voltage falls, the resistance value increases. Above a particular voltage, the varistor becomes low-ohmic and thereby prevents a further voltage increase. The above-mentioned placeholder can be fitted, for example, during production of the at least one over voltage protection component between varistors/varistor blocks of the at least one over voltage protection component. By means of the at least one measuring assembly, the state, e.g. the temperature, of the varistors/varistor blocks can be monitored by the system. Accordingly, the signal can be e.g. changed and reflected at the measuring component of the at least one measuring assembly in dependence on the state, e.g. the temperature, of one or more varistors such that information about the state, e.g. the temperature, of the one varistor or of the multiple varistors is able to be derived from the reflected signal by the evaluation unit.

In other words, a varistor is an electrical resistor which has a voltage-dependent resistance (variable resistor=varistor). There are varistors based e.g. on silicon carbide and metal oxide. Metal-oxide varistors (MOV) are often used nowadays.

For example, the at least one over voltage protection component can have at least one metal-oxide varistor (MOV), for example multiple MOVs, or can be in the form of at least one MOV, for example multiple MOVs. That is to say, the above-mentioned varistors can each be in the form of an MOV varistor. MOVs/MOV varistors are special varistors, i.e. likewise protection components, whose resistance value is voltage-dependent. MOV varistors have a very high resistance in the normal state. Above a particular threshold voltage, the resistance value falls abruptly. In the case of an over voltage, MOV resistors respond very quickly, usually within nanoseconds, and dissipate the over voltage correspondingly quickly.

The at least one measuring assembly is coupled with the connection assembly, for example, such that the signal reflected at or In the at least one measuring assembly in dependence on the state, e.g. the temperature, of the at least one measuring assembly is able to be coupled into the connection assembly. The connection assembly is configured and arranged, for example, so as to guide the reflected signal in the direction of the evaluation unit. The connection assembly is coupled with the evaluation unit, for example, such that the reflected signal is able to be coupled into is the evaluation unit. The evaluation unit is configured, for example, to derive information about the state, e.g. the temperature, of the at least one over voltage protection component from the reflected signal. The transmission unit and the evaluation unit can be arranged at the same location, e.g. In a common entity. In this case, the path of the signal from the transmission unit to the measuring assembly can correspond at least largely to the path of the signal from the measuring assembly to the evaluation unit. Alternatively, the transmission unit and the evaluation unit can be arranged at different locations. In this case, the path of the signal from the transmission unit to the measuring assembly can differ from the path of the signal from the measuring assembly to the evaluation unit in that there is arranged at a point of the path, e.g. before the transmission unit, a beam splitter which is configured to divert the reflected signal to the evaluation unit.

The at least one measuring component of the at least one measuring assembly is connected to the fiber of the at least one measuring assembly, for example, such that the signal reflected at the at least one measuring component of the at least one measuring assembly in dependence on the state, e.g. the temperature, of the at least one measuring assembly is able to be coupled into the fiber of the at least one measuring assembly. The fiber of the at least one measuring assembly is configured and arranged, for example, so as to guide the reflected signal in the direction of the connection assembly. The fiber is coupled with the connection assembly, for example, such that the reflected signal is able to be coupled into the connection assembly. The connection assembly is configured and arranged, for example, so as to guide the reflected signal in the direction of the evaluation unit. The connection assembly is coupled with the evaluation unit, for example, such that the reflected signal is able to be evaluated by the evaluation unit. The evaluation unit is configured, for example, to derive information about the state, e.g. the temperature, of the at least one over voltage protection component from the reflected signal.

The system can have a computing unit connected to the evaluation unit. The computing unit is configured to determine from the information about the state, e.g. the temperature, of the at least one over voltage protection component a probability of failure of the at least one over voltage protection component. Limit values, for example, can be defined for this purpose. The limit values can describe, for example, the basic temperature during operation or the decay time following an event such as a lightning strike. This can be achieved e.g. via a lookup table. Alternatively, the system can be designed to be self-learning and to determine limit values itself via long-term measurement of the normal state.

The computing unit can be connected to the evaluation unit wirelessly and/or by a wired connection. The computing unit and the evaluation unit can communicate with one another via the wireless and/or wired connection. For example, the evaluation unit can transmit the information about the state, e.g. the temperature, of the at least one over voltage protection component to the computing unit via the wireless and/or wired connection.

The computing unit can be configured to determine a possible failure of the at least one over voltage protection component if the determined probability of failure of the at least one over voltage protection component exceeds a predetermined limit value. Additionally or alternatively, the computing unit can be configured to determine a possible failure of the at least one over voltage protection component if the determined probability of failure of the at least one over voltage protection component differs by a predetermined value from a determined probability of failure of one or more further of the at least one over voltage protection component.

The computing unit can be configured to warn of the possible failure of the at least one over voltage protection component if the determined probability of failure of the at least one over voltage protection component exceeds a predetermined limit value. Additionally or alternatively, the computing unit can be configured to warn of the possible failure of the at least one over voltage protection component if the determined probability of failure of the at least one over voltage protection component differs by a predetermined value from a determined probability of failure of one or more further of the at least one over voltage protection component.

The warning can be given by means of a visual and/or acoustic signal. There may be mentioned purely by way of example a warning via an automatically generated email or a pop-up message on a smartphone, tablet or other device.

The at least one over voltage protection component can be configured as a plurality of over voltage protection components. Each of the plurality of over voltage protection components can have a measuring assembly described herein. In other words, if multiple over voltage protection components are to be monitored, one of the at least one measuring assembly can be arranged/present in each of the multiple over voltage protection components. Each of the at least one measuring assembly can have a fiber, e.g. optical fiber, and a measuring component connected to the fiber. The state, e.g. the temperature, of each of the plurality of over voltage protection components can, as described, be monitored.

The at least one over voltage protection component can be configured for the over voltage protection of a series compensation of a power system. In particular, the at least one over voltage protection component can be configured for the over voltage protection of a series compensation, such as e.g. a series-connected capacitor bank, of a power system. Such a series compensation, such as e.g. a series-connected capacitor bank, is referred to as fixed series compensation (FSC). Generally, series compensation is used in power systems, such as power transmission systems, in order to increase the transmission capacity of lines by controlling the impedance, in order actively to control the line impedance (and thus increase the power system stability in general) and/or, in particular in regions with a high probability of lightning strike, in order to permit the rapid reestablishment of operation (since e.g. a thyristor-protected capacitor does not have to be cooled down following a disruption). Examples of series compensation which may be mentioned at this point include solid capacitors and also thyristor-switched capacitors.

Fixed series compensation is used, for example, to optimize the efficiency of large power transmission systems. By installing a series capacitive reactance on a long aerial line (typically over 200 km), both the angular deviation and the voltage drop are reduced, which increases the loadability and stability of the line. For the technological solution of series compensation, series-connected capacitors are used in transmission lines. The devices are accommodated on a platform, which is completely isolated from the voltage system. The capacitor and the over voltage protection are both accommodated on the (steel) platform. The over voltage protection is a key factor for the design, since the capacitor bank must withstand the transmitted fault current even in the case of a severe, nearby disruption, e.g. a lightning strike in the overhead line. The primary over voltage protection typically has non-linear varistors, a fast-acting protection device (CapThor) and a rapid shunt switch. The secondary protection is often made possible by ground-mounted electronics, which responds to signals of the optical current converter of the high-voltage circuit.

The over voltage protection of a fixed series compensation usually has multiple varistors, normally MOVs, stacked one above the other. The varistors can form a so-called column, or an arrester. If a high voltage occurs in the system, the varistors switch in the transmitting direction and convert this over voltage into heat. Multiple, is usually up to 22, arresters are connected in parallel on an FSC platform, which arresters together protect the installation from unforeseeable effects. Providers of such installations attempt to reduce the number of arresters if possible, but it has hitherto not been possible to properly calculate the required quantity of arresters.

The inner structure of an arrester is usually segmented. Accordingly, there can be in an arrester components with relevant functions as well as the placeholders already mentioned, which contribute towards achieving a certain overall height. These placeholders are sometimes also referred to as spacers. The above-mentioned fiber, for example optical fiber, can be introduced into these placeholders. The fiber can, however, also be arranged at other locations or components in the arrester. The measuring component can in each case be arranged on the varistors, e.g. MOVs. For example, fibers can in each case be arranged on or in an associated placeholder of an arrester, and measuring components can in each case be arranged on an associated varistor, e.g. MOV.

As described, varistors degrade over the course of their operating time as a result of different effects, such as, for example, the ingress of moisture, local discharges as a result of poor contact between varistors, contamination in the housing, which leads to unsuitable voltage distribution in the stack, and mechanical damage as a result of thermal overloading, e.g. following a high-current event.

Varistors are permanently conductive if a critical voltage value is exceeded and must therefore be replaced, since it is otherwise no longer possible to switch on the installation. The varistor in question cannot readily be identified using systems available hitherto. Long downtimes are therefore to be expected. The monitoring described herein of the state of varistors offers the possibility of accurate and/or targeted prediction regarding the lifetime and/or maintenance cycles of an arrester, or of individual varistors.

The signal, e.g. analog optical signal, described herein and reflected at the measuring component can be processed further by the evaluation unit so that the data can be processed by the computing unit, such as supervisory control and data acquisition (SCADA) systems. In other words, raw data can be provided by the at least one measuring assembly and the evaluation unit, which raw data are then processed further by software running on the computing unit in order to calculate possible failures of the at least one over voltage protection component and optionally warn of such failures as a precautionary measure. Targeted maintenance can thus be is planned at an early stage.

In addition, the affected over voltage protection component can be determined. For example, the system can have for this purpose at least one switch, e.g. at least one optical switch. According to a possible embodiment, a switch can be provided for each arrester. According to a further possible embodiment, a switch can be provided for each varistor. Regardless of the exact number of switches, the state of the switch, or switches, is known on measurement, and thus the location at which the measurement is carried out is also known. The measurement therefore takes place with direct traceability to the over voltage protection component, such as e.g. to the varistor. The affected over voltage protection component can thereby be named, e.g. depending on the number of switches, at least more accurately or even accurately and replacement can take place at least in a more targeted manner or even in a targeted manner. The complex search for the defective part, i.e. the defective over voltage protection component, can be reduced or, for example, omitted completely. In systems known from the prior art, the core components are checked in specified cycles. With as accurate knowledge as possible of the state of the components, the maintenance cycles can be reduced to a necessary or prescribed minimum. As an early warning system, the computing unit and the software running thereon can be coupled/combined with weather forecasts. Lightning strikes can, for example, lead to damage. However, lightning strikes do not usually result in a complete failure. Such damage can be detected with the system. The probability that a further lightning strike will cause the already damaged over voltage protection component to fall completely (which in turn leads to the installation as a whole being shut down) is (extremely) high. Replacing the affected over voltage protection component at an early stage therefore prevents failure of the installation.

By means of the described system there is therefore provided a solution with which inter alia outdoors high-voltage components such as over voltage protection components can be monitored in respect of their state, e.g. their temperature. Existing systems for transformer monitoring do not have transmission paths leading from earth- to high-voltage potential. The technical parameters of such existing solutions and the price structure thereof make these solutions unattractive.

According to a second aspect of the invention, a method for monitoring the state of at least one over voltage protection component is provided. The method is carried out by the system according to the first aspect. The method comprises the following steps: transmission of a signal by means of the transmission unit; coupling of the transmitted signal into the connection assembly; guiding of the coupled-in signal through the connection assembly in the direction of the at least one measuring assembly; coupling of the signal guided through the connection assembly in the direction of the at least one measuring assembly into the at least one measuring assembly; reflection of the signal in or at the at least one measuring assembly in dependence on the state of the at least one over voltage protection component, such that information about the state of the at least one over voltage protection component is able to be derived from the reflected signal by the evaluation unit.

Although some details have been described only in relation to the system according to the first aspect, these can correspondingly be implemented in the method according to the second aspect.

The present disclosure will be explained further with reference to figures. These figures show, schematically:

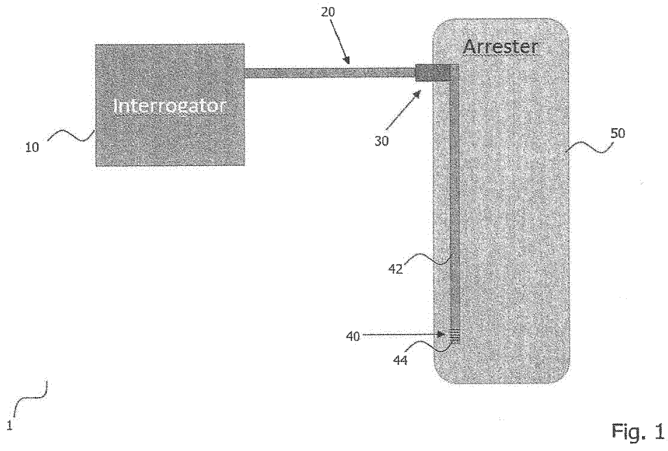

FIG. 1 a possible configuration of a system for monitoring the state of at least one over voltage protection component according to an exemplary embodiment;

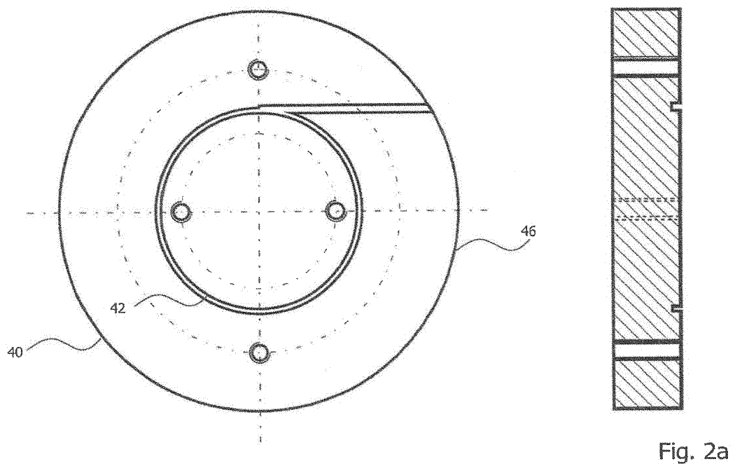

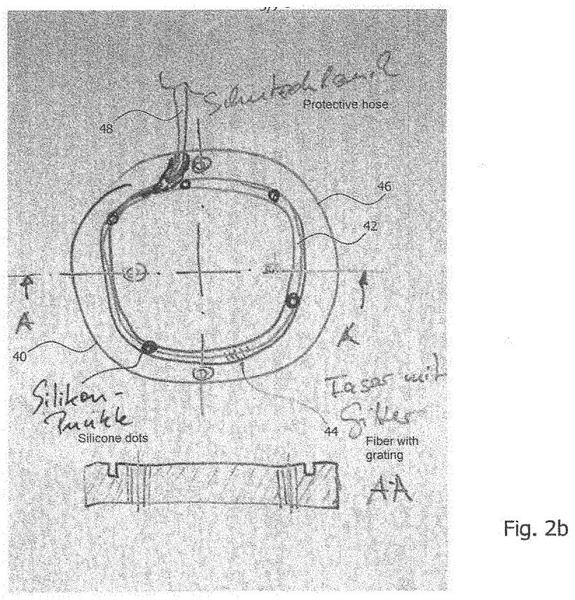

FIG. 2a a possible configuration of a measuring assembly of the system from FIG. 1 according to an exemplary embodiment;

FIG. 2b a possible configuration of a measuring assembly of the system from FIG. 1 according to an exemplary embodiment;

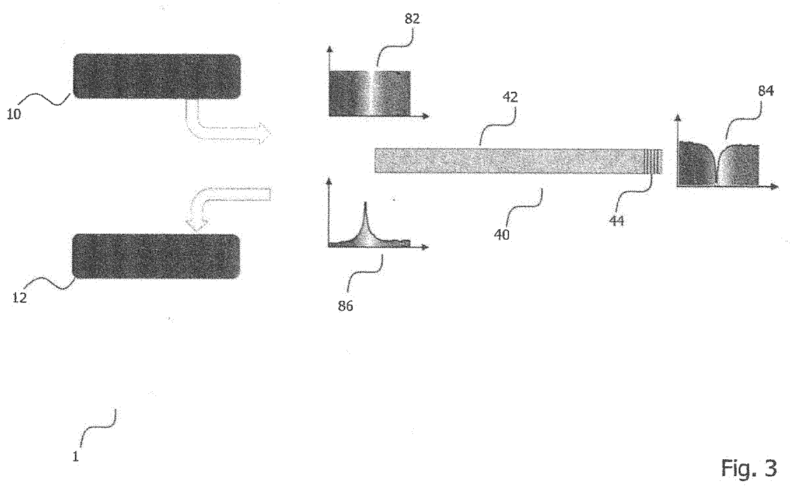

FIG. 3 a possible configuration of a system for monitoring the state of at least one over voltage protection component according to an exemplary embodiment;

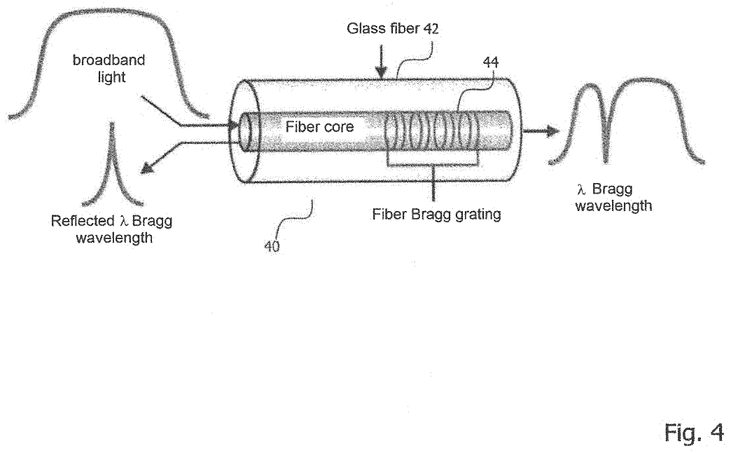

FIG. 4 a possible configuration of a system for monitoring the state of at least one over voltage protection component according to an exemplary embodiment;

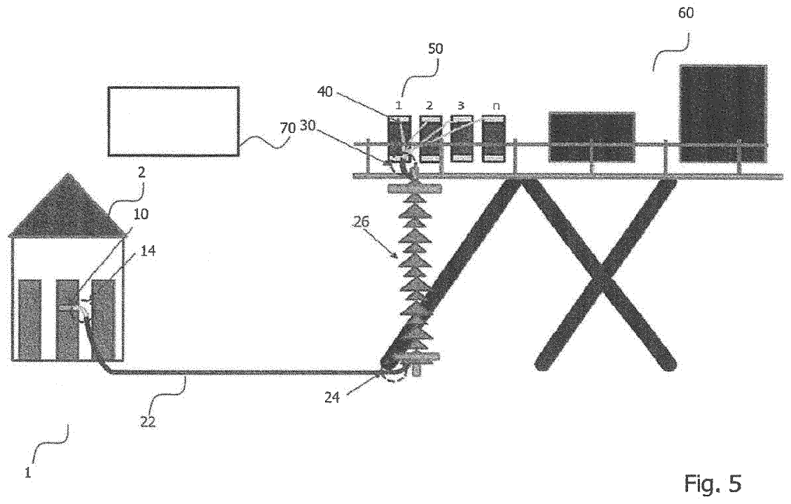

FIG. 5 a possible configuration of a system for monitoring the state of at least one over voltage protection component according to an exemplary embodiment; and

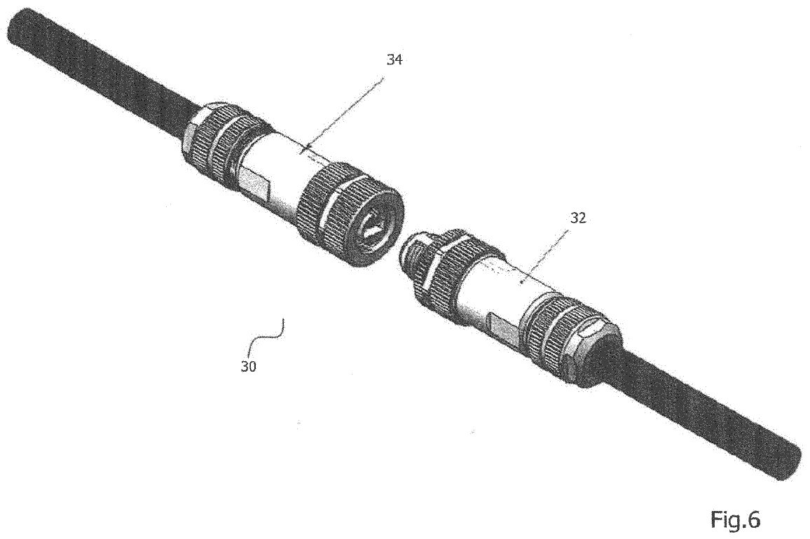

FIG. 6 a possible configuration of a connecting device of the system from one of FIG. 1 or 3 to 5.

In the following, without being limited thereto, specific details are set out in order to provide a complete understanding of the present disclosure. It will, however, be clear to a skilled person that the present disclosure can be used in other exemplary embodiments which may differ from the details set out hereinbelow. For example, there are described hereinbelow specific configurations and forms of a system, which are not to be regarded as limiting. By way of example, the invention will be described hereinbelow in part in relation to its use with fixed series compensation. The invention is, however, not limited to this application.

Fixed series compensation (FSC) is a preferred solution for optimizing the efficiency of large power transmission systems. By installing a series capacitive reactance on a long aerial line (typically over 200 km), both the angular deviation and the voltage drop are reduced, which increases the loadability and stability of the line. For the technological solution of series compensation, series-connected capacitors (capacitor banks) are used in transmission lines. The devices are usually accommodated on a platform, which is completely isolated from the voltage system. The capacitor and the over voltage protection are both accommodated on the (steel) platform. The over voltage protection is of particular importance for the design, since the capacitor bank must withstand the transmitted fault current even in the case of a severe, nearby disruption, e.g. a lightning strike in the overhead line. The primary over voltage protection typically contains non-linear varistors, a fast-acting protection device (CapThor) and a rapid shunt switch. The secondary protection is made possible by ground-mounted electronics, which responds to signals of the optical current converter of the high-voltage circuit.

The over voltage protection has varistors, usually metal-oxide varistors (MOV), stacked one above the other, which form a column, or an arrester. A varistor is an electrical resistor which has a voltage-dependent resistance (variable resistor=varistor). There are varistors based on silicon carbide and metal oxide. The mentioned metal-oxide varistors (MOV) are widely used nowadays.

If a high voltage occurs in the system, the varistors switch in the transmitting direction and convert this over voltage into heat. Multiple, and usually up to 22, arresters are connected in parallel on an FSC platform, which arresters together is protect the installation from unforeseeable effects. However, the amount of this protective function alone accounts for about 20% of the total system costs. For this reason, attempts are made to reduce the number of arresters if possible. However, there has not hitherto been a reliable possibility for precisely calculating the required quantity of arresters.

Varistors degrade over the course of their operating time as a result of different effects, such as, for example, the ingress of moisture, local discharges as a result of poor contact between varistors, contamination in the housing, which leads to unsuitable voltage distribution in the varistor stack, and mechanical damage as a result of thermal overloading following a high-current event.

Varistors are permanently conductive if a critical voltage value is exceeded and must be replaced, since it is otherwise no longer possible to switch on the installation. The varistor in question cannot readily be identified. Long downtimes are therefore to be expected. Monitoring the state of varistors is desirable in order to make an accurate prediction regarding the lifetime and maintenance cycles of an arrester, or of individual varistors.

Such monitoring of the state of MOVs is at present not reliably possible. Current approaches can be divided into optical, electrical and thermal measurement principles. At present, the only known optical measuring device is the optical-electrical surge counter. This measures the number of excessive increases and provides them with a timestamp. Electrical forms of such counters are likewise known. In the case of electrical measurement principles, leakage current meters, third harmonic current measurement and partial discharge detection can further be distinguished.

In so-called surge counters, two electrodes are arranged parallel to one another. In the event of activation of an MOV, there is a current flashover between the electrodes, which results in an optical signal which can be measured with an optical fiber and evaluated by a receiver. Since the measurement principle is based on a flashover between the electrodes, it necessarily results in a degradation of the electrode surface. According to the manufacturer's specifications, the electrodes must be replaced in the case of degradation for uninterrupted operation. The measurement takes place optically. The duration and number of the flashovers can also be recorded. However, it is not possible, without unscrewing the device, to determine whether the electrodes are degraded (have holes). A general check of is these measuring devices is further recommended following thunderstorms. The measuring method has a high maintenance outlay for the installed electrodes alone. The maintenance outlay increases when it is considered that the end of the optical fiber also experiences impairment effects in the event of a lightning strike. Furthermore, it is not clear how the end of the optical fiber degrades over time in the case of flashovers (light arcs are an established method for melting optical fibers; the fiber is here exposed to a light arc on each MOV activation). Finally, optical measurement of the flashover does not permit cascading/combining of multiple sensors and a single receiver (the measurement must be carried out continuously in order not to miss a flashover; the measurement window is ms, i.e. an event may possibly be missed when switches are fitted; in the case of cascading, it is not possible to identify which event comes from which arrester, or from which column).

Leakage current meters are further known. These are measuring devices for determining the leakage current. The leakage current is composed of a resistive current (5-20%, 10 μA-several hundred μA) and a capacitive current (80-95%, 0.2 mA-0.3 mA). Since the leakage current is dominated by the capacitive current, error-free measurement of the resistance current is extremely susceptible to electromagnetic noise in practice. Various compensation methods are used for distinguishing the resistive current from the capacitive current, such as, for example, a constant phase shift method, a modified shift current method, a multi-coefficient compensation method, active power measurement, a least squares method, etc. Most widely used are 1) oscilloscopes with sensitive voltage and resistive current probes and 2) the third harmonic method. Devices are known which identify discharges with amplitudes above 10 A, evaluate the entire leakage current and the resistive current and prepare statistics. The evaluation is based on analysis of the third harmonic. The data can be read out from a distance of 60 m (optionally 120 m), so that the service personnel do not need access authorization to the substation. The device does not need an external power supply since it can be operated by solar cells and the applied electrical field.

Overall, leakage current meters are relatively inexpensive. However, digital signal processing is necessary. Furthermore, under IEC 60099-5, the use of this method for to calculating the resistance current and online monitoring is actually limited by the electromagnetic noise that occurs. Generally, the measurement results are dependent in part on the type and manner of grounding. Damage to the arrester cannot be concluded directly from the measurement of high resistance currents alone. Additional measurements are necessary.

Third harmonic current sensors are further known. The non-linear nature of MOVs leads to harmonic frequencies in the spectrum. A voltage characteristic with an ideal sinusoidal profile would not lead to harmonic components of the current intensity. The presence of harmonic components in the voltage characteristic leads to a component of the third harmonic frequency. The harmonic component depends on the amplitude of the resistive current and the degree of non-linearity (function of voltage and temperature). The third harmonic is composed of a capacitive and a resistive current component. Ageing phenomena always lead to an increase in the resistive component. A common method for determining the resistive component of the leakage current is to measure the component of the third harmonic and convert it into the resistive component with a correction factor. However, the current flow through the resistor is dependent on the temperature. Furthermore, complex and expensive technology for online measurement is necessary for the numerical analysis. Finally, digital signal processing is required.

Partial discharge detectors (partial discharge measurement) are further known. A partial discharge detector detects localized electrical flashovers in solids or liquids, which occur when a high voltage is applied. The charge actually moved is thereby measured in pico-coulombs in dependence on time. The measurement procedure takes into consideration the detection, classification and localization of the discharge. Such measurements are cost-intensive. Portable devices are scarcely available. Distinguishing the discharge from background noise is not a trivial matter. Moreover, partial discharges occur only in wet weather.

Measurement of the current-voltage characteristic (Vref testing) is further known. An MOV has a characteristic non-linear current-voltage characteristic, which is provided by the manufacturer on handover. This changes over the lifetime of the MOV as a result of ageing of the arrester. Measuring the characteristic and comparing it with the characteristic provided by the manufacturer (measurement at reference voltage Vref at a fixed current intensity) allows the state of ageing to be determined. This procedure is expedient only to measure a single MOV, which must be isolated from the system as a whole. The method is cost-intensive. Access to the installation is necessary.

Thermal cameras are further known. With a thermal camera, the temperature of an arrester can be determined from a distance of several tens of meters. A difference of about 10° C. between loaded arresters can indicate a fault with an arrester. Thermal cameras are inexpensive and work contactlessly and quickly (no installation necessary). However, an arrester has a thermal signature only when loaded and cannot be evaluated when it is unloaded. Each arrester must be measured individually. Furthermore, the field of view is limited (=limited measuring field (view shielded by surrounding installations). A long-term installation is not available.

Of the above-mentioned solutions, only the leakage current meter and the surge counter lend themselves to permanently installed state monitoring. However, they have numerous disadvantages, some of which have been mentioned above. There is a need for an improved measuring method and an improved monitoring system.

FIG. 1 shows a system for monitoring the state of at least one over voltage protection component. The system 1 has a transmission unit 10. The system 1 has a connection assembly 20 coupled with the transmission unit 10. The system 1 further has at least one measuring assembly 40 coupled with the connection assembly 20. In the example of FIG. 1, the connection assembly 20 is coupled with the measuring assembly 40 via a connecting device 30. The measuring assembly 40 is configured for arrangement in or on at least one over voltage protection component 50. The over voltage protection component 50 in the example from FIG. 1 is configured as part of an arrester, such as e.g. as a varistor of an arrester, or as an arrester. The measuring assembly 40 has, purely by way of example, a fiber 42 and a measuring component 44 connected to the fiber 42.

A plan view of an example of a measuring assembly 40 is shown in FIGS. 2a and 2b. In this example, the measuring assembly 40 has a metallic housing 46. The fiber 42 is guided into the metallic housing 46 via a protective hose 48. The fiber 42 has the form of a coil or spiral and is wound in the metallic, cylindrical housing 46 in a spiral shape or, when seen in a plan view, in a circular shape upwards or downwards. At one end of the fiber 42 there is arranged a measuring component 44. The cylindrical metallic housing 46 can be the above-described placeholder of an arrester, for example of the arrester from FIG. 1.

The measuring component 44 can have a fiber Bragg grating or can be in the form of a fiber Bragg grating. Examples of measurement assemblies 40 having such a fiber Bragg grating are shown, in connection with other components of the system 1, in FIGS. 3 and 4. Monitoring of the state of the over voltage protection component 50 (e.g. of part of the arrester or of the arrester) from FIG. 1 can take place as follows.

In FIGS. 3 and 4, the system 1, by way of example, is in the form of an optical system, i.e. the system 1 operates with an optical signal. Accordingly, in relation to FIGS. 3 and 4, some of the components are referred to as optical components. According to FIG. 3, the system 1 has an evaluation unit 12 coupled with the at least one optical measuring assembly 40. The transmission unit 10 is to this end configured to transmit an optical signal. An example of a spectrum 82 of the optical signal is shown in FIG. 3. An example of a wavelength profile of the optical signal is shown in FIG. 4.

The optical transmission unit 10 and the optical connection assembly 20 (not shown in FIGS. 3 and 4 for the sake of simplicity) are coupled such that the optical signal is coupled into the optical connection assembly 20. The optical connection assembly is configured and arranged so as to guide the coupled-in optical signal in the direction of the at least one optical measuring assembly 40. The optical connection assembly 20 and the at least one optical measuring assembly 40 are coupled with one another, for example via the connecting device 30 from FIG. 1, such that the optical signal is coupled into the optical fiber 42 of the at least one optical measuring assembly 40. The optical fiber 42 and the optical measuring component 44 of the at least one optical measuring assembly 40 are connected to one another such that the optical signal is guided in the direction of the optical measuring component 44. The optical measuring component 44 of the at least one measuring assembly 40 is configured to reflect the optical signal in dependence on a state of the at least one over voltage protection component 50. This results in a reflected spectrum 86 of the optical signal (see FIG. 3) or a reflected wavelength range of the optical signal (see FIG. 4). Another portion of the optical signal is transmitted to the optical measuring component 44. This results in a transmitted spectrum 84 of the optical signal (see FIG. 3) or a transmitted wavelength range of the optical signal (see FIG. 4). The evaluation unit 12 is configured to derive information about the state of the at least one over voltage protection component 50 from the reflected optical signal. For example, the evaluation unit 12 is configured to derive information about the state of the at least one over voltage protection component 50 from the reflected spectrum of the optical signal (FIG. 3) or from the reflected wavelength range of the optical signal (FIG. 4). In particular, the signal reflected at the optical measuring component 44 (with the reflected spectrum or the reflected wavelength range) can be guided through the optical fiber 42 in the direction of the evaluation unit 12. After leaving the optical fiber 42, the reflected signal can be deflected in a targeted is manner to the evaluation unit 12 by means of a beam splitter, for example.

The fiber-optic state monitoring can, as mentioned, be carried out by means of so-called fiber Bragg gratings (FBG) as the measuring component 44. These components have a local refractive index structure (length about 20 mm) which, at a chosen wavelength, reflects and/or transmits an optical signal, such as a laser signal, by a predetermined degree similarly to a mirror. When external influences, such as e.g. tensile stress, compressive stress, temperature or moisture, act on such a component, the degree of reflection or transmission at the chosen wavelength changes measurably. The reflected spectrum or the reflected wavelength range of the optical signal thereby change. This change relative to the normal state can be detected by the evaluation unit 12.

The fiber-optic sensor system can, as described, be used for measuring the state of one or more MOVs. A metal cylinder having the construction illustrated in FIGS. 2a and 2b can be used for this purpose. The dimensions of the metal cylinder can be adapted to the MOV to be measured. For example, the metal cylinder can be a placeholder of an arrester. In order to be able to vary the conductivity of current and temperature of the metal cylinder, different materials can be chosen (aluminum alloys, copper, etc.). Since the optical measuring method is based on reflection, the reflectivity of the FBG can be chosen to be high (50-99.99%) in order to maximize the signal to be measured and thus be able to use as simple a measurement technique as possible. Laying the fiber 42 in a circular or spiral shape compensates for a possible radially acting tensile stress, which occurs as a result of thermal expansion of the metal cylinder in dependence on the temperature.

As an alternative to laying the fiber 42 cylindrically, it is also possible to lay the fiber 42 linearly. In this case, the fiber 42 can be fixed in an additional housing (e.g. a stainless steel tube) in order to decouple the thermally caused tensile stress.

A fiber-optic measuring method for determining the state, e.g. the temperature, of an over voltage protection component 50, e.g. an MOV, is thus provided. By means of a temperature sensor system, a significant added value in respect of function/ageing monitoring of arresters and predictive maintenance of the installation as a whole can be achieved.

FIG. 5 shows, schematically, a possible configuration of a system 1 according to an exemplary embodiment. The system 1 from FIG. 5 is also described by way of example with the transmission of an optical signal. The transmission of other signals and the conversion thereof (after transmission) into optical signals, for example, is conceivable; the system 1 can in this case be adapted to the transmission of such other signals. The system 1 has a control system 2, shown by way of example in FIG. 5 in the form of a control house. A transmission unit 10 is provided in the control system 2. The system 1 further has an underground cable 22. The underground cable 22 is coupled/connected to the transmission unit 10 via a coupling point 14. The underground cable 22 is part of the above-mentioned connection assembly 20. The system 1 further has an isolator 26. The isolator 26 is coupled/connected to the underground cable 22 via a coupling point 24. The isolator 26 is part of the above-mentioned connection assembly 20. The system 1 further has at least one over voltage protection component 50. In FIG. 5, purely by way of example and without being limited thereto, four over voltage protection components 50 are shown, all of which are denoted with the reference numeral 50 hereinbelow and in FIG. 5 are additionally provided with the designations 1, 2, 3 and n in order to indicate that any desired number of from 1 to n over voltage protection components 50 can be provided. The over voltage protection components 50 are connected to the isolator 26 via a connecting device 30. Purely by way of example, the over voltage protection components 50 in FIG. 5 are each in the form of an arrester or part of an arrester. Each of the arresters has one or more varistors. The system 1 further has a computing unit 70.

There are further shown in FIG. 5 multiple series-connected capacitors, which together form a series-connected capacitor bank (FSC) 60. Although the FSC 60 is shown in FIG. 5, it is not necessarily part of the system 1.

Following the optical path from FIG. 5, the hardware components of the system 1 and the individual components thereof will be explained in detail.

The evaluation unit 12 and the transmission unit 10 in FIG. 5 are by way of example a common unit (also referred to as an interrogator), i.e. the transmission unit 10 and the evaluation unit 12 are by way of example merged into a common unit. The transmission unit 10 can alternatively also be an entity separate from the evaluation unit 12. The transmission unit 10 is configured to transmit analog optical signals. In the following, reference is made to one of these analog optical signals as the optical signal. The transmission unit 10 is coupled with the underground cable 22 via the coupling point 14 such that the optical signal is coupled into one or more optical fibers arranged in the underground cable 22.

The underground cable 22 is configured to transmit the optical signal between the transmission unit 10/evaluation unit 12 and the isolator 26. The underground cable 22 is thus configured on the one hand to guide/carry the signal coupled into the underground cable 22 from the transmission unit 10 via the coupling point 14 in the direction of the isolator 26. The underground cable 22 is configured for use outdoors. The underground cable 22 therefore meets requirements of UV resistance, underground layability, freedom from halogen, flame resistance and/or compatibility with the construction products regulation of the European Union (EU) which has in the meantime become binding.

The isolator 26 is designed for use outdoors. For example, the isolator 26 is in the form of a so-called composite isolator. The isolator 26 further has one or more optical conductors, for example optical waveguides (LWL), which is/are guided through the isolator 26 (not shown separately in FIG. 5). The isolator 26 is coupled with the underground cable 22 via a coupling point 24, such that the optical signal is coupled from the underground cable 22 into the optical conductor, for example the LWL, of the isolator 26.

The isolator 26 is connected to the over voltage protection components 50 via a connecting device 30. The connecting device 30 is designed to be suitable for outdoors. The connecting device 30 further has a sufficient high-voltage resistance. One or more optical conductors, for example LWLs, or optical fibers, which guide(s) the optical signal run inside the connecting device 30.

The connecting device 30 can be in the form of, for example, a plug connection 30, as is shown by way of example in FIG. 6. At the end of the connecting device 30 there is provided a plug 32, which is likewise shown by way of example in FIG. 6. The plug connection 30 and thus also the plug 32 are designed to be suitable for outdoors. The plug 32 permits releasable connection to the over voltage protection components 50. This permits a simple and low-risk installation. The plug connection and thus also the plug 32 are water-tight and metallic.

The (water-tight) plug 32 is attached during installation to a type of coupling, which is mounted at the upper end of each over voltage protection component 50. This coupling seals the transition region between the plug 32 and the over voltage protection components 50 so that no function-Impairing moisture is able to penetrate into the over voltage protection components 50 and the optical signal (the light signal) can nevertheless pass through this transition region. In FIG. 5, the coupling is in the form of a wall feedthrough or has a wall feedthrough.

In each over voltage protection component 50 there is provided an optical measuring assembly 40. For example, there is a measuring assembly 40 inside each over voltage protection component 50. This measuring assembly 40 is provided e.g. on the input side with a plug 34, which is attached to the coupling internally during production of the respective over voltage protection component 50. From there, an optical fiber 42 which is suitable for high temperatures leads in each case to the measuring component 44 of each measuring assembly 40. Each of the over voltage protection components 50 can have such an optical fiber 42. This optical fiber 42 is embedded with the measuring component 44 in a placeholder of an arrester, which is installed during production of the over voltage protection components 50, for example, between the varistors, for example MOVs or MOV blocks, of the over voltage protection components 50. The state of these MOVs or MOV blocks is monitored. This embedding of the measuring assembly 40, for example of the fiber 42 and/or of the measuring component 44, in the placeholder takes place such that, ideally, no mechanical stress acts/occurs on the measuring assembly 40, in particular the measuring component 44, since the MOVs or MOV blocks are fixed during manufacture of the respective over voltage protection component 50 with pressure, which also acts on the placeholder. However, pressure is also detected by the measuring assembly 40, in particular the measuring component 44. This pressure is not to be measured, however. For example, only the temperature of each MOV or each MOV block or of each over voltage protection component 50 or of each arrester is to be determined, and pressure could thus (dramatically) falsify the measurements.

The optical signal is changed at the measuring component 44, which can also be referred to as a measurement probe, and reflected back. The reflected optical signal travels on the same path in the other direction to the evaluation unit 12, which by way of example is part of the transmission unit 10. In other words, the measuring component 44 of each of the measurement arrangements 40 (of each of the over voltage protection components 50) is connected to its associated optical fiber 42 such that the optical signal changed and reflected at the respective measuring component 44 in dependence on the state, e.g. the temperature, of the respective over voltage protection component 50 is coupled into the optical fiber 42. The respective optical fiber 42 is configured and arranged so as to guide the reflected optical signal in the direction of the isolator 26. The respective optical fiber 42 is coupled with the isolator 26 such that the reflected optical signal is coupled into the optical conductor, for example LWL, of the isolator 26. The optical conductor, for example LWL, of the isolator 26 is configured and arranged so as to guide the reflected optical signal in the direction of the underground cable 22. The underground cable 22 is configured and arranged so as to guide the reflected optical signal in the direction of the evaluation unit 12. The ground cable 22 is coupled with the evaluation unit 12 such that the reflected optical signal is able to be coupled into the evaluation unit 12. The evaluation unit 12 is configured, for example, to derive information about the state, e.g. the temperature, of the over voltage protection components 50 from the reflected optical signal. The reflected optical signal can thus be read, analyzed and converted into temperature values by the evaluation unit 12. The temperature values can be read out via one or more interfaces and forwarded to the computing unit 70, e.g. a computing center.

In the computing unit 70, further processing of the data can take place. For example, the data obtained by means of the above-described hardware components can be inputted into software of the computing unit 70. The computing unit compares the measured values of all the monitored over voltage protection components 50 and warns if one or more over voltage protection components 50 are behaving differently than the rest. On the basis of the switching state of at least one optical switch provided in the system 1, it is possible to determine at least approximately the particular over voltage protection component 50 at which the measurement is carried out. The switching state of the optical switch can, for example, precisely identify the over voltage protection component 50 in question. The system 1 can, for example, have such a switch. Alternatively, one such switch can be provided in the system 1 for each arrester. Alternatively such a switch can be provided in the system 1 for each over voltage protection component 50 or for each varistor (e.g. for each MOV). Since the measurement points can be identified, it is also possible to say at least approximately accurately which of the over voltage protection components 50 is behaving extraordinarily and a replacement can be carried out in a targeted manner. This reduces the downtime of the installation considerably. Trends can also be identified and a replacement can be recommended at an early stage in accordance with a schedule. The actual behavior of the over voltage protection components 50 (the layout of which is based on theoretical models) can likewise be specified more precisely on the basis of the software. The number of over voltage protection components 50 to be installed could thereby optionally be reduced. All rules (when and how the software responds and what warning messages or recommendations it outputs) can be defined within the software. Project-specific requirements (which are different each time) can thus be fulfilled and nevertheless there is an added value.

The state measurement explained above can be summarized in relation to the example of temperature monitoring in the following two steps.

In a first step, a correlation between the temperature, the current-voltage characteristic and the state (of ageing) of the MOVs can be established by the long-term measurement of the temperature of various types of MOVs. For this purpose, loading tests can be carried out in a targeted manner on MOVs (e.g. electrical discharges), in which the decay curve of the temperature is measured. The curve can be fitted and the fit coefficients for the present MOV types can be determined. Furthermore, the current-voltage characteristics can be determined and the temperature can be measured in dependence on the current intensity. Measured v/a the current intensity, a higher temperature will be established in a more highly aged MOV at a fixed current value than in a less aged MOV. This trend is likewise to be expected for the profile of the voltage.

In a second step, an evaluation of the state (of health) of the/each MOV can be carried out by means of a correlation of environmental influences (e.g. weather data, lightning strikes) with the measured temperature for known current intensities and voltages on the basis of the data from the first step. Absolute values of the temperature can thereby serve as alarm thresholds. Likewise, a pattern recognition can be carried out with neural networks, which establishes a correlation between events in the system, the weather and the temperature profile. For example, a series of lightning strikes will usually manifest itself in the profile of the temperature of the MOV over time. The data so processed from the computing unit 70 or a memory unit connected to the computing unit 70, such as e.g. a cloud, can be converted into a warning message for the end user. The failure of an entire arrester can thus be avoided. As a result of the predictability of failures, there is a substantial added value.

Accordingly, a system 1 (measuring system) for monitoring the temperature of over voltage protection components 50 (components at high-voltage level) is provided. The system 1 can be used, for example, for the more efficient layout of FSC installations and also for reducing downtime and for reducing the maintenance outlay of such installations. If such installations fail, the network is inefficient and costs the operator a large amount of money in a very short time. The system 1 accordingly increases the efficiency of FSC installations.

Furthermore, the number of MOVs in FSC installations is today dimensioned on the basis of very old thermal models. These models are often not realistic or lead to (wholly) over dimensioned installations. The monitoring function provided by the system 1 can help to reduce the dimensioning of the installations. This also leads to increases in efficiency.

Furthermore, the downtime of medium-voltage installations can be reduced with the system 1. Maintenance intervals can be planned. In the case of defects, the defective component can be identified remotely and the necessary replacement part can be acquired in a planned manner. Overall, this results in considerable efficiency advantages for operators of medium-voltage installations. Such a system 1 may optionally be of interest for insurers, in order to be able to control risks.

Although the system 1 has been described in relation to such FSC installations, the applicability of the system 1 is not limited thereto. It can also be used, for example, for charging cables in the field of e-mobility. Furthermore, the system 1 can also be used in other fields in which over voltage protection components 50, such as arresters generally or surge arresters in particular, are used. There too, the system 1 can be used for state monitoring. A further example is measurement of the temperature of other electrical components in the high-voltage (HV) field with a planar surface.

1. A system for monitoring the state of at least one over voltage protection component, wherein the system has:
a transmission unit;
a connection assembly coupled with the transmission unit;
at least one measuring assembly coupled with the connection assembly, which measuring assembly is able to be arranged in or on at least one over voltage protection component; and
an evaluation unit coupled with the at least one measuring assembly;
wherein
the transmission unit is configured to transmit a signal,
the transmission unit and the connection assembly are coupled such that the signal is able to be coupled into the connection assembly,
the connection assembly is configured and arranged so as to guide the coupled-in signal in the direction of the at least one measuring assembly,
the connection assembly and the at least one measuring assembly are coupled with one another such that the signal is able to be coupled into the at least one measuring assembly, and
the at least one measuring assembly is configured to reflect the signal, in dependence on a state of the at least one over voltage protection component, such that information about the state of the at least one over voltage protection component is able to be derived from the reflected signal by the evaluation unit,
wherein the at least one measuring assembly has a fiber and a measuring component connected to the fiber,
wherein the fiber of the at least one measuring assembly is configured and arranged so as to guide the signal coupled into the at least one measuring assembly in the direction of the measuring component of the at least one measuring assembly,
wherein the measuring component:
has a fiber Bragg grating or is in the form of a fiber Bragg grating.

2. The system as claimed in claim 1, wherein the measuring component:
has one or more crystals or is in the form of one or more crystals; or
has one or more fluorescent dyes or is in the form of one or more fluorescent dyes.

3. The system as claimed in claim 1, wherein the connection assembly has:
an underground cable coupled with the transmission unit; and
an isolator coupled with the underground cable and with the at least one measuring assembly; wherein
the transmission unit and the underground cable are coupled with one another such that the signal transmitted by the transmission unit is able to be coupled into the underground cable,
the underground cable is configured and arranged so as to guide the coupled-in signal through the underground cable in the direction of the isolator,
the isolator has at least one conductor, for example an optical waveguide, and is coupled with the underground cable such that the signal guided through the underground cable in the direction of the isolator is able to be coupled into the at least one conductor of the isolator,
the at least one conductor of the isolator is configured and arranged so as to guide the signal coupled into the at least one conductor through the at least one conductor in the direction of the at least one measuring assembly, and
the isolator is releasably coupled with the at least one measuring assembly such that the signal guided through the at least one conductor of the isolator in the direction of the at least one measuring assembly is able to be coupled into the at least one measuring assembly.

4. The system as claimed in claim 3, wherein the system further has a connecting device and the connecting device has:
a connecting component having at least one fiber which is able to be connected or is connected to the isolator such that the signal guided through the conductor of the isolator is able to be coupled into the at least one fiber of the connecting component; and
a plug connected to the connecting component, which plug is configured to establish a releasable connection between the connecting component and the at least one measuring assembly.

5. The system as claimed in claim 1, wherein
the at least one measuring assembly is able to be coupled or is coupled with the connection assembly such that the reflected signal is able to be coupled into the connection assembly,
the connection assembly is configured and arranged so as to guide the signal coupled into the connection assembly in the direction of the evaluation unit,
the connection assembly and the evaluation unit are coupled such that the reflected signal is able to be coupled into the evaluation unit, and
the evaluation unit is configured to derive information about the state of the at least one over voltage protection component from the reflected signal.

6. The system as claimed in claim 1, wherein the system has a computing unit connected to the evaluation unit, which computing unit is configured to determine from the information about the state of the at least one over voltage protection component a probability of failure of the at least one over voltage protection component.

7. The system as claimed in claim 6, wherein the computing unit is configured to determine a possible failure of the at least one over voltage protection component if the determined probability of failure of the at least one over voltage protection component exceeds a predetermined limit value and/or if the determined probability of failure of the at least one over voltage protection component differs by a predetermined value from a determined probability of failure of one or more further of the at least one over voltage protection component.

8. The system as claimed in claim 6, wherein the computing unit is configured to warn of the possible failure of the at least one over voltage protection component if the determined probability of failure of the at least one over voltage protection component exceeds a predetermined limit value and/or if the determined probability of failure of the at least one over voltage protection component differs by a predetermined value from a determined probability of failure of one or more further of the at least one over voltage protection component.

9. The system as claimed in claim 1, wherein the state of the over voltage protection component exhibits a temperature, a tensile stress, a compressive stress and/or a degree of moisture of the over voltage protection component or wherein the state of the over voltage protection component is a temperature, a tensile stress, a compressive stress and/or a degree of moisture of the over voltage protection component.

10. The system as claimed in claim 1, wherein the at least one over voltage protection component is configured as a plurality of over voltage protection components.

11. The system as claimed in claim 1, wherein the at least one over voltage protection component has a varistor or is in the form of a varistor, in particular has a metal-oxide varistor or is in the form of a metal-oxide varistor; and/or
wherein the signal transmitted by the transmission unit is an optical signal or a digitally modulated signal.

12. The system as claimed in claim 1, wherein the at least one over voltage protection component is configured for the over voltage protection of a series compensation of a power system, in particular for the over voltage protection of a series-connected capacitor bank of a power system.

13. A method for monitoring the state of at least one over voltage protection component by means of the system as claimed in claim 1, wherein the method comprises the following steps:
transmission of a signal by means of the transmission unit;
coupling of the transmitted signal into the connection assembly;
guiding of the signal coupled into the connection assembly through the connection assembly in the direction of the at least one measuring assembly;
coupling of the signal guided via the connection assembly in the direction of the at least one measuring assembly into the at least one measuring assembly; and
reflection of the optical signal in or at the at least one measuring assembly in dependence on the state of the at least one over voltage protection component, such that information about the state of the at least one over voltage protection component is able to be derived from the reflected signal by the evaluation unit.

14. (canceled)

15. (canceled)
